(19) United States
(12) Patent Application Publication
(10) Pub. No.: US 2023/0395456 A1
(43) Pub. Date: Dec. 7, 2023

(54) HEAT REMOVAL IN INTEGRATED CIRCUITS WITH TRANSISTORS AND DOUBLE-SIDED METAL INTERCONNECTS

(71) Applicant: Intel Corporation, Santa Clara, CA (US)

(72) Inventors: Jean-Pierre Njante, Mesa, AZ (US); Telesphor Kamgaing, Chandler, AZ (US)

(73) Assignee: Intel Corporation, Santa Clara, CA (US)

(21) Appl. No.: 17/831,100

(22) Filed: Jun. 2, 2022

(51) Int. Cl. H01L 23/367; H01L 23/528; H01L 23/373

(52) U.S. Cl. CPC H01L 23/3672; H01L 23/3738; H01L 23/5283

(57) ABSTRACT

Thermally conductive, electrically insulating materials and their manufacture on integrated circuit (IC) dies. An IC die may include a substrate with transistors on one side and, on the first and/or a second side, electrically insulating materials enhanced with thermally conductive materials. Such an IC die may be included in a system with a power supply. Such materials may be co-deposited, or interspersed, or interleaved together in a composite material.

### BACKGROUND

For greater computational capabilities, integrated circuit (IC) device sizes have been decreased. Accordingly, current densities have increased, which requires improved heat dissipation from sensitive, heat-generating semiconductor structures. However, the electrically insulating materials used in ICs are typically poor thermal conductors.

FIGS. 1A and 1B illustrate cross-sectional profile views of conventional IC dies 100, including transistors 101 and dielectric material 110. In FIG. 1A, transistors 101 are on a front-side 103 of a substrate 102. Power metallization structures 120 and signal metallization structures 121 are routed through dielectric material 110 to connect transistors 101 to first-level interconnect (FLI) interfaces 122. Since dielectric material 110 is not very thermally conductive, substrate 102 is relied upon for transport of heat generated by transistors 101.

In FIG. 1B, transistors 101 are on again on a surface of substrate 102, but in this example dielectric material 110 is both above and below substrate 102, thermally isolating transistors 101. Metallization structures 120, 121 connect transistors 101 to FLI interfaces 122. In FIG. 1B, power metallization structures 120 and signal metallization structures 121 are routed through the lower dielectric material 110 on a back-side 104 of substrate 102, through substrate 102, and through the upper dielectric material 110 on the front-side 103. Although a heat spreader 130 of arbitrarily high thermal conductivity is attached through a bonding layer 140, transistors 101, substrate 102, and metallization structures 120, 121 are thermally insulated by dielectric material 110.

It is with respect to these and other considerations that the present improvements have been needed. Such improvements may become critical with the ever-increasing demand to manufacture small, densely packed transistors separated from each other and from other structures by electrically insulating materials.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements, e.g., with the same or similar functionality. The disclosure will be described with additional specificity and detail through use of the accompanying drawings:

FIGS. 1A and 1B illustrate cross-sectional profile views of IC dies, in accordance with convention;

FIG. 2 illustrates various processes or methods for enhancing electrically insulating materials for improved heat removal from IC dies, in accordance with some embodiments;

FIG. 3 illustrates a cross-sectional profile view of an example IC die, including transistors and an enhanced electrical isolation for improved heat removal, in accordance with some embodiments;

FIG. 4 illustrates a cross-sectional profile view of an example IC die, including transistors and an enhanced electrical isolation for improved heat removal, in accordance with some embodiments;

FIG. 5 illustrates a cross-sectional profile view of an example IC die, including transistors and enhanced electrical isolations for improved heat removal, in accordance with some embodiments;

FIGS. 6A, 6B, 6C, and 6D illustrate cross-sectional profile views of example IC dies, including enhanced electrical isolation for improved heat removal, in accordance with some embodiments;

FIGS. 7A and 7B illustrate cross-sectional profile views of systems, including heat sinks and IC dies with enhanced electrical isolation for improved heat removal, in accordance with some embodiments;

FIGS. 8A, 8B, 8C, and 8D illustrate cross-sectional profile views of systems, including heat sinks and IC dies with enhanced electrical isolation for improved heat removal, in accordance with some embodiments;

FIG. 9 illustrates a diagram of an example data server machine employing IC dies with enhanced electrical isolation for improved heat removal, in accordance with some embodiments; and

FIG. 10 is a block diagram of an example computing device, in accordance with some embodiments.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. The various embodiments, although different, are not necessarily mutually exclusive. For example, a particular feature, structure, or characteristic described herein, in connection with one embodiment, may be implemented within other embodiments without departing from the spirit and scope of the claimed subject matter.

References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled.

The terms “over,” “to,” “between,” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The terms “coupled” and “connected,” along with their derivatives, may be used herein to describe structural relationships between components. These terms are not intended as synonyms for each other. Rather, in particular embodiments, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship, an electrical relationship, a functional relationship, etc.).

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and recitations of “top,” “bottom,” “above,” and “below” refer to relative positions in the z-dimension with the usual meaning. However, embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified in the specific context of use, the term “predominantly” means more than 50%, or more than half. For example, a composition that is predominantly a first constituent means more than half of the composition is the first constituent. The term “primarily” means the most, or greatest, part. For example, a composition that is primarily a first constituent means the composition has more of the first constituent than any other constituent. A composition that is primarily first and second constituents means the composition has more of the first and second constituents than any other constituent.

Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional,” “profile,” and “plan” correspond to orthogonal planes within a cartesian coordinate system. Thus, cross-sectional and profile views are taken in the x-z and y-z planes, and plan views are taken in the x-y plane. Typically, profile views in the x-z plane are cross-sectional views. Where appropriate, drawings are labeled with axes to indicate the orientation of the figure.

Intentional electrical connections are made in integrated circuit (IC) dies between circuit components, usually with electrical conductors or semiconductors. To otherwise electrically isolate IC components from each other, they are surrounded by electrically insulating materials. Some electrical insulating materials (which may be low-k or conventional dielectric materials) are used for their comparatively low relative permittivity, which minimizes parasitic capacitive interference between components in a circuit. Most electrical insulating materials are thermally insulating as well, so when they surround circuit components that generate heat, they can inhibit heat dissipation from those often-sensitive circuit components.

As described below, materials, structures, and techniques are disclosed to improve the thermal performance of IC dies. Thermally conductive materials can be mixed, interspersed, interleaved, etc., with, e.g., conventional dielectric materials to form electrically insulating materials that can be used as electrical isolation while improving heat removal from IC dies. Improving the thermal performance of IC dies also improves the reliability and electrical performance of the IC dies.

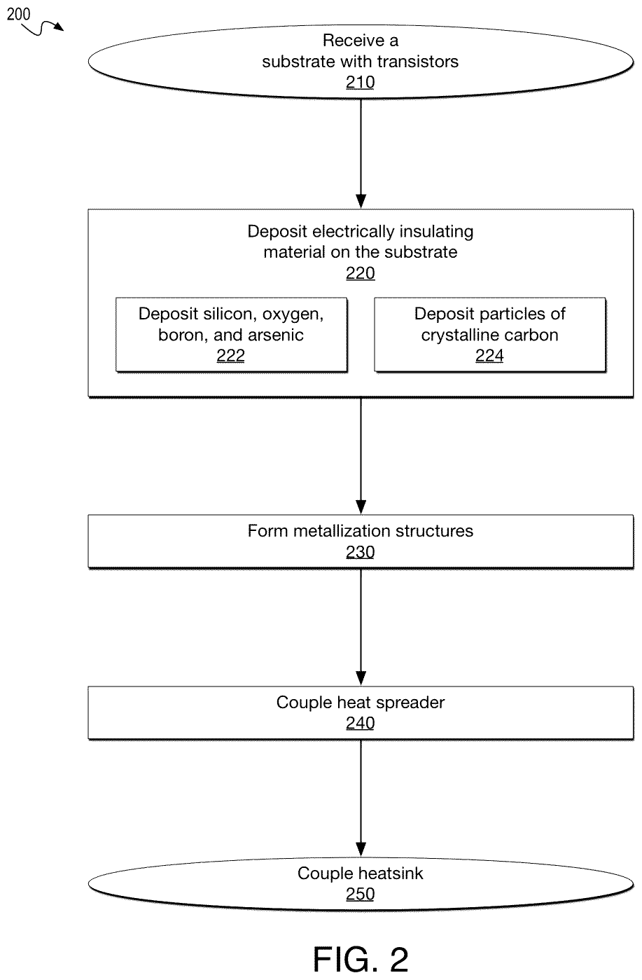

FIG. 2 illustrates various processes or methods for forming enhanced electrically insulating materials for improved heat removal from IC dies, in accordance with some embodiments. FIG. 2 shows a process 200 that includes operations 210-250. Some operations shown in FIG. 2 are optional. FIG. 2 shows an example sequence, but the operations can be done in other sequences as well, and some operations may be omitted. Some operations can also be performed multiple times before other operations are performed. Some operations are included in other operations. Generally, using the further operations described below, a thermally conductive electrically insulating material is deposited on at least one side of an IC die substrate with transistors. The enhanced electrically insulating material forms electrical isolation with improved heat transfer capabilities relative to conventional dielectric material. Metallization structures, such as interconnects, are formed through the electrical isolation. Heat spreaders or heat sinks are coupled to the IC die. This sequence can also be reversed.

In operation 210, a substrate is received with transistors on at least one side. In some embodiments, transistors are on the frontside of the substrate. In some embodiments, transistors are on the backside. In some embodiments, transistors are on both sides. In some embodiments, the substrate is a semiconductor material that transistors can be formed out of and on, e.g., crystalline silicon or a III-V material, such as gallium arsenide or gallium nitride. Any suitable semiconductor or other material can be used. The transistors can be of the same material as the substrate or, e.g., deposited on the substrate.

In operation 220, an electrically insulating material is deposited over one or both sides of the substrate. To enhance the heat transfer characteristics of the electrically insulating material, a material of a relatively low relative permittivity is doped with a material of higher thermal conductivity. The more thermally conductive material may have a higher relative permittivity, so an amount of each to include in the electrically insulating material may be determined to enhance heat transfer to the extent permissible for a given IC device. In some embodiments, the electrically insulating material includes silicon and oxygen. As one example, silicon dioxide has a relative permittivity suitable for many IC device applications. However, other materials having a sufficiently wide band gap to be suitable electrical insulators, such as boron arsenide and various forms of crystalline carbon, are significantly more thermally conductive than silicon-based oxides. In some embodiments, silicon dioxide is doped, or otherwise combined, with boron arsenide to form an electrically insulating material with a sufficiently low relative permittivity and with enhanced thermal conductivity. Characteristics of electrically insulating materials can be adjusted by controlling the relative amounts (e.g., concentrations or thicknesses) of the at least two materials. For example, the thermal conductivity of silicon dioxide can be enhanced to higher thermal conductivity by increasing the concentration of, e.g., boron arsenide.

In some embodiments, the thermal conductivity of a first material, such as silicon dioxide, may be enhanced by layering it with a second material, such as a layer of crystalline carbon. For example, an average thermal conductivity of an electrically insulating material can be increased by increasing the thickness of a crystalline carbon layer and lowering the thickness of the silicon dioxide layer. As described further below, a layer of crystalline carbon may be cubic crystalline, e.g., diamond. In other embodiments, a layer of crystalline carbon is hexagonal crystalline, e.g., graphite or graphene.

Operations 222, 224, and/or other operations can be performed alone or in combination as an implementation of operation 220 to deposit an electrically insulating material having enhanced thermal properties. Methods of combining the materials and depositing electrically insulating materials can be varied. For example, such techniques may be based on the compositions of the materials, the desired microstructure, or the arrangement of the layers to be formed. In some embodiments, multiple thermally conductive materials of different chemical composition are deposited as distinct layers of an electrically insulating material. In some embodiments, the dielectric material is grown, e.g., thermally, or otherwise deposited, on a substrate before introducing a more thermally conductive material as a dopant, filler, or secondary component of a composite insulative material.

In accordance with some embodiments, an electrically insulating material is formed at operation 222 by chemical vapor deposition (CVD). In some embodiments, precursor gases that include silicon and oxygen are mixed in the gas phase with secondary precursor gases that will dope the electrically insulative material deposited so as to be more thermally conductive. For example, precursors gases comprising boron and arsenic may be mixed with silane and an oxidizer in the desired ratios to deposit a homogenous electrically insulating material. In other embodiments, different materials of distinct composition are deposited separately to form a heterogenous composite electrically insulating material. For example, a layer of silicon dioxide may be deposited by CVD, plasma-enhanced CVD (PECVD), or atomic layer deposition (ALD). A layer of a more thermally conductive material, such as boron arsenide, may then be deposited over the silicon dioxide layer, for example by CVD or physical vapor deposition (PVD). In other embodiments, filler particles of a thermally conductive material are interspersed in or on a matrix material. In some such embodiments, the thermally conductive filler material is substantially boron arsenide while the matrix material is substantially silicon and oxygen (e.g., SiO₂). Such composites may be deposited by PVD or by cold spray techniques. In still other embodiments, laser CVD is used to deposit on a silicon dioxide layer. For such embodiments, the interval density of filler particles is increased to increase the boron arsenide concentration in the electrically insulating material.

In some embodiments, particles or layers of crystalline carbon are deposited at operation 220. In operation 224, for example, particles of crystalline carbon may be deposited under or over a precursor layer of dielectric material, such as silicon dioxide, or other electrically insulating material comprising at least silicon and oxygen, and perhaps further including other constituents, such as, but not limited to, boron and arsenic. In some embodiments, cubic crystalline carbon particles, e.g., diamond, are cold sprayed or deposited by PVD onto the substrate. Such particles may be clad in another dielectric material. For example, diamond particles with coated with silicon dioxide or another oxide may be cold sprayed or PVD deposited. In some embodiments, crystalline carbon particles are cold sprayed or PVD deposited concurrently with other particles, e.g., onto a layer of silicon dioxide or directly upon a surface of the crystalline substrate. For example, diamond particles may be co-deposited with particles of silicon dioxide. In some embodiments, particles of crystalline carbon coated with an oxide are sprayed or PVD deposited over (or at least between) metallization structures in or over a layer of silicon dioxide.

In some embodiments, cold-spray techniques provide low-temperature, no-vacuum, high-throughput deposition of, e.g., crystalline carbon onto a substrate, including over another dielectric material and/or metallization structures. Cold spray may be used to deposit a single material, e.g., crystalline carbon, or mixtures of materials, e.g., silicon dioxide and crystalline carbon. For example, in some embodiments, a layer of silicon dioxide is deposited by any suitable means and particles of crystalline carbon are cold sprayed in a layer over the silicon dioxide. In some such embodiments, the particles of crystalline carbon are cold sprayed over metallization structures that are formed over a planarized layer of silicon dioxide. In the same or other embodiments, materials are co-deposited by cold spray. For example, first and second materials, e.g., particles of crystalline carbon and silicon dioxide, can be mixed and cold sprayed together over a substrate and/or metallization structures. The particles can be mixed and fed together into the cold-spray system, or mixed and cold sprayed together after being fed separately.

Cold-spray systems with independent feed and control systems for each of two or more materials may provide enhanced mixing and deposition. With independent feed and control systems, two or more materials can be mixed better. For example, two materials can be heated separately to different temperatures before being mixed together in the cold-spray nozzle, which can be beneficial when mixing materials with different melting points. Further, the two materials can be fed into physically distinct delivery positions, which allows for more control and different kinds of mixing. In some embodiments, a first material is fed into the convergent section of a cold-spray nozzle and a second material is fed into the divergent section. Such independent feeding allows, e.g., the first material to be accelerated in the nozzle before the second material is introduced. This earlier feeding also allows for further heating of the first material after introduction in the nozzle but before the second material is introduced.

Cold-spray systems with independent feed and control systems can better and more efficiently deposit mixtures of two or more materials. For example, mixtures with different concentrations of two materials can be co-deposited without the need for a new deposition setup, e.g., changing out feed materials. In some embodiments, a layer includes two materials mixed at a first concentration at the bottom of the layer, a second concentration at the top of the layer, and a gradient between the bottom and top with the concentrations varying continuously and linearly with vertical position in the layer. Other embodiments use independent feed and control systems for more than two materials. In some embodiments, a layer includes particles of different size but the same or similar chemical composition mixed together with the relative portions of each size varying continuously and linearly with vertical position in the layer. In embodiments with distinct layers of different feed materials, independent feed and control systems allow for processing without the need for a new deposition setup, e.g., changing out feed materials.

Whether using cold spray or another method, deposition parameters can be adjusted to adjust the relative concentrations of the various constituent materials in an enhanced electrically insulating material. For example, the concentration and/or size of crystalline carbon (e.g., diamond or graphite) particles is varied to adjust the average thermal conductivity of an enhanced electrically insulating material over at least some temperature window relevant to the operation of the IC device.

In some embodiments of operation 220, multiple layers of different materials or composition are deposited, including at least one of at least crystalline carbon. While in some embodiments, particles are interspersed into another material, in some embodiments, particles are deposited in a layer over a layer of another material. In some embodiments, an enhanced electrically insulating material is deposited by spraying or PVD depositing a layer of crystalline carbon particles over a layer of silicon dioxide or an electrically insulating material of silicon dioxide and boron arsenide. In some embodiments, a layer of crystalline carbon particles is sprayed or PVD deposited over metallization structures in or over a layer of silicon dioxide. In some such embodiments, the layer of crystalline carbon particles is substantially conformal to the underlying metallization structures. In other such embodiments, the layer of crystalline carbon particles planarizes or otherwise fills gaps between underlying metallization structures.

Deposition parameters can be adjusted to adjust the relative concentrations of the various constituent materials in an enhanced electrically insulating material. For layered embodiments, the thickness of a layer of crystalline carbon particles relative to the thickness of another material layer, such as silicon dioxide, is varied to adjust the relative concentration of crystalline carbon in an enhanced electrically insulating material.

In some embodiments where crystalline carbon particles, e.g., diamond, are cold sprayed in a layer over a layer of electrically insulating material, the particles are interspersed in a layer of dielectric material. In some embodiments, different particle sizes are deposited in distinct layers of electrically insulating material. In some embodiments where smaller metallization structures and finer pitches are present, smaller particles are deposited around these metallization structures, and larger particles are deposited around levels of metallization having larger feature pitches. Thinner layers of crystalline carbon particles may also be deposited over metallization features of smaller pitch, while thicker layers of crystalline carbon particles are deposited over metallization features of larger pitch. In some embodiments, crystalline carbon particles of significantly different diameters are deposited within one electrically insulating material layer. Such a mixing of particle sizes may help control the size of air gaps between particles and adjust the relative permittivity of a layer.

In operation 230, metallization structures are formed through the electrically insulating material with the electrically insulating material to function as electrical isolation. The structures can be formed according to any known techniques before, concurrently with, or after laterally adjacent electrically insulating materials are deposited. In some embodiments, metallization structures are formed over the substrate or previously formed electrically insulating materials before depositing more electrically insulating material over the metallization structures. For example, metallization structures may be deposited over a planar surface of a bottom dielectric material, such as silicon dioxide, and then particles of crystalline carbon may then be deposited between and/or over the metallization structures. A top dielectric material, such as silicon dioxide, may then be deposited over the crystalline carbon and metallization structures, and planarized to complete the deposition of electrically insulating material having enhanced thermal properties.

In some embodiments, a portion of electrically insulating material is etched away, and metallization structures are formed within the void formed by the etching. Another portion of the electrically insulating material may then be formed over the metallization structures.

In operation 240, a heat spreader is coupled to the structures of the IC die. A heat spreader can help remove heat generated in the IC die to adjacent structures, such as heat sinks, where the heat can be further dissipated, e.g., to a fluid coolant. In some embodiments, the heat spreader is coupled to an enhanced electrically insulating material, e.g., to a surface of an enhanced electrically insulating material. In some such embodiments, the heat spreader is coupled with a thermally conductive adhesive or bonding oxide. In other embodiments, the heat spreader is coupled with a direct compression bond. In some embodiments, the heat spreader is coupled to the IC die through a substrate, e.g., a package substrate.

In operation 250, a heat sink is coupled to the IC die. The heat sink can be designed to maximize heat transfer to a fluid coolant, e.g., air, low-boiling point liquids, or refrigerants. In some embodiments, the heat sink is connected to a heat spreader atop the IC die. In some embodiments, the heat sink is connected to a package substrate with the IC die. In some such embodiments, the heat sink is connected to a package substrate underneath or opposite the IC die. In some embodiments, the heat sink is connected to metallization structures of the IC die.

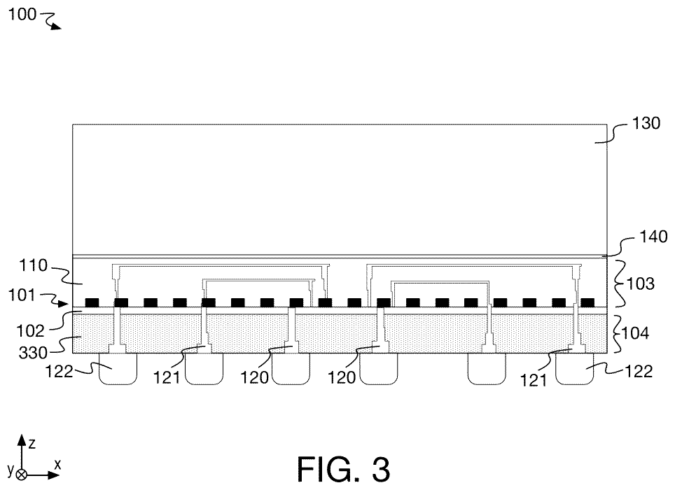

FIG. 3 illustrates a cross-sectional profile view of an IC die 100, including transistors 101 and an enhanced electrical isolation 330 for improved heat removal, in accordance with some embodiments. IC die 100 includes an array of transistors 101 on front-side 103 of substrate 102. Dielectric material 110 is adjacent and above substrate 102. Electrical isolation 330 is adjacent and below substrate 102 on back-side 104. Electrical isolation 330 comprises electrically insulating material that has an enhanced, higher thermal conductance (i.e., lower thermal resistance) than dielectric material 110. Electrical isolation 330 provides a lower resistance path for heat dissipation downward from any heat-generating structures, e.g., transistors 101. Metallization structures 120, 121 connect transistors 101 to first-level interconnect (FLI) interfaces 122. Power metallization structures 120 are routed through electrical isolation 330 on back-side 104. Power metallization structures 120 provide electrical power to transistors 101 through substrate 102 from an external power supply via FLI interfaces 122. Signal metallization structures 121 are routed through electrical isolation 330 on back-side 104, through substrate 102, and through dielectric material 110 to front-side 103 of substrate 102. Signal metallization structures 121 provide signal paths for, e.g., control and I/O signals to and from transistors 101 via FLI interfaces 122. In FIG. 3, a heat spreader 130 is attached to dielectric material 110 through a bonding layer 140.

Transistors 101 are on front-side 103 of substrate 102, but some portions of the surface remain exposed such that dielectric material 110 is adjacent to substrate 102. In some embodiments, substrate 102 is a semiconductor material, e.g., crystalline silicon, and transistors 101 include the same material. In some embodiments, transistors 101 are made of a semiconductor material, and substrate 102 is a different material. Transistors 101 may have any device architecture, such as, but not limited to, bipolar junction transistors (BJTs) or field effect transistors (FETs). Transistors, such as non-planar transistors, e.g., ribbonFETs, having channels divided up into many, smaller subchannels often have increased current densities. Other examples, in addition to FETs with nanoribbon channels, have nanowire or nanosheet channels. In some embodiments, electrical isolation 330 is used for arrays of such high-current, heat-generating transistors 101.

In the example of FIG. 3, electrical isolation 330 has a higher thermal conductance than the thermal conductance of dielectric material 110 above substrate 102. This higher thermal conductance of electrical isolation 330 improves heat removal from, e.g., transistors 101 downward through substrate 102.

Thermal energy generated in transistors 101 can be dissipated to a structure below IC die 100. In some embodiments, heat is removed from transistors 101 through electrical isolation 330 to a package substrate (not depicted) below IC die 100 and a heat sink thermally coupled to the package substrate.

Electrical isolation 330 includes at least two materials, e.g., a first dielectric material and a second material that improves the thermal conductivity of the first dielectric material. The first dielectric material has the same chemical composition as dielectric material 110. The insulating dielectric material may have a comparatively lower dielectric constant (i.e., relative permittivity), and the thermally conductive material has a relatively higher thermal conductivity. In some embodiments, electrical isolation 330 is an insulating dielectric material doped with a material having a higher thermal conductivity and a higher relative permittivity. In some embodiments, electrical isolation 330 is silicon dioxide doped with a material having a higher thermal conductivity and a higher relative permittivity. In some embodiments, electrical isolation 330 includes silicon dioxide interspersed with boron arsenide. Silicon dioxide has a lower dielectric constant than boron arsenide, and boron arsenide is more thermally conductive than silicon dioxide. In some embodiments, the concentration of boron arsenide is higher to increase the thermal conductance of electrical isolation 330. In some embodiments, electrical isolation 330 is mostly boron arsenide deposited with minimal amounts of silicon dioxide.

In some embodiments, electrical isolation 330 is an insulating dielectric material interspersed in a material having a higher thermal conductivity and a higher relative permittivity. In some embodiments, electrical isolation 330 comprises small particles of crystalline carbon interspersed in a material having a lower relative permittivity and a lower thermal conductivity. In some embodiments, electrical isolation 330 includes small particles of crystalline carbon interspersed in silicon dioxide. In some such embodiments, the crystalline carbon is cubic crystalline, e.g., diamond. The concentration of the more thermally conductive dopants or particles interspersed in the insulating dielectric material can be adjusted to tune the relative permittivity and the thermal conductivity. In this way, the characteristics of electrical isolation 330 can be optimized for certain applications and embodiments.

In some embodiments, electrical isolation 330 includes multiple layers, at least some of which include an insulating dielectric material and a thermally conductive material. These layers can be thought of as parts of a single electrical isolation 330 or as separate, adjacent electrical isolations 330. In some embodiments, electrical isolation 330 includes alternating layers of an insulating dielectric material and a more thermally conductive material. The thicknesses of the alternating layers can be adjusted to tune the relative permittivity and the thermal conductivity of electrical isolation 330. The characteristics of electrical isolation 330 can be optimized for certain applications and embodiments. In some embodiments, electrical isolation 330 includes a layer of silicon dioxide over a layer of crystalline carbon, e.g., diamond, particles. In some embodiments, electrical isolation 330 includes multiples layers of silicon dioxide with one or more layers of crystalline carbon interleaved between the silicon dioxide layers. Here, the term “interleaved” refers to at least two different layers arranged in alternating fashion, e.g., a layer of a first type over a layer of a second type.

In some embodiments, electrical isolation 330 includes two layers, one with a first insulating dielectric material and a first thermally conductive material, and a second with a second insulating dielectric material and a second thermally conductive material. In some embodiments, electrical isolation 330 includes two layers, each with the same insulating dielectric material and the same thermally conductive material. In some embodiments, electrical isolation 330 includes more than two layers, one or more with a first insulating dielectric material and one or more others with a second insulating dielectric material. In some such embodiments, the one or more layers with a first insulating dielectric material have a first thermally conductive material, and the one or more others with a second insulating dielectric material have a second thermally conductive material. In other such embodiments, the one or more layers with a first insulating dielectric material have a second thermally conductive material, and the one or more others with a second insulating dielectric material have a first thermally conductive material.

Electrical isolation 330 may be used selectively in certain parts of IC die 100. In some embodiments, dielectric material 110 has a lower relative permittivity than electrical isolation 330, and electrical isolation 330 has a higher thermal conductivity than dielectric material 110. In some such embodiments, electrical isolation 330 improves heat removal from areas of IC die 100 with less-dense metallization, and dielectric material 110 surrounds signal metallization structures 121 with tighter line pitches and conducting control and I/O signals with higher frequencies. In some embodiments, power metallization structures 120 and electrical isolation 330 are above substrate 102, and signal metallization structures 121 are routed through dielectric material 110 under substrate 102.

Metallization structures 120, 121 through electrical isolation 330 may be similar to those structures routed through a conventional dielectric material 110. For example, in some embodiments, metallization structures 120, 121 may be in voids etched in an electrical isolation 330 of predominantly silicon dioxide and boron arsenide, with more electrical isolation 330 deposited over metallization structures 120, 121. In some embodiments, vertical holes in electrical isolation 330, e.g., formed by laser drilling or etching, includes metallization structures 120, 121 formed in the holes. In some such embodiments, these metallization structures 120, 121 form vias through multiple layers of electrical isolation 330.

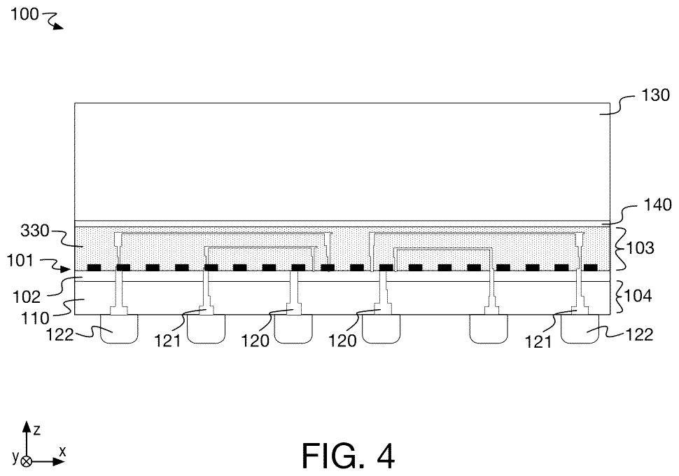

FIG. 4 illustrates a cross-sectional profile view of an example IC die 100, including transistors 101 and an enhanced electrical isolation 330 for improved heat removal, in accordance with some embodiments. As shown in FIG. 4, transistors 101 are on substrate 102. Here, dielectric material 110 is adjacent and below substrate 102 on back-side 104, and electrical isolation 330 is adjacent and above substrate 102 on front-side 103. Electrical isolation 330 has a lower thermal resistance (and a higher thermal conductance) than dielectric material 110. Metallization structures 120, 121 connect transistors 101 to FLI interfaces 122. Heat spreader 130 is attached to electrical isolation 330 through bonding layer 140.

Electrical isolation 330 improves heat removal from transistors 101 and substrate 102 by enhancing thermal dissipation upward through electrical isolation 330 to heat spreader 130. In some embodiments, electrical isolation 330 is used above substrate 102 (rather than below) to dissipate thermal energy to heat spreader 130 rather than to a structure below IC die 100. In some embodiments, IC die 100 is above one or more IC dies 100 with a thermally resistive dielectric material 110 above transistors 101. Thermal energy generated in transistors 101 can be dissipated to a structure above IC die 100. In some embodiments, heat is removed from transistors 101 through electrical isolation 330 and heat spreader 130 to a heat sink above IC die 100 and thermally coupled to heat spreader 130.

Heat spreader 130 is a thermally conductive material, more thermally conductive than the insulating dielectric material of dielectric material 110, and helps dissipate heat off of IC die 100. In some embodiments, heat spreader 130 is or includes a metal, such as copper. In some embodiments, heat spreader 130 includes a crystalline material, such as crystalline silicon or silicon carbide. In some embodiments, heat spreader 130 is part of a larger structure, e.g., a carrier wafer used for other mechanical or handling purposes during earlier processing, before being diced out with IC die 100. In some embodiments, heat spreader 130 is predominantly a first material and is doped with a second material, e.g., to be more thermally conductive. For example, heat spreader 130 may be crystalline silicon or glass doped with a second material.

Heat spreader 130 is joined to electrical isolation 330 through bonding layer 140. In some embodiments, bonding layer 140 is a thermal interface material, such as a thermally conductive adhesive or epoxy. In some embodiments, bonding layer 140 is a thermally conductive oxide. In some embodiments, no extra material is used for bonding layer 140, and bonding layer 140 is an interface layer where the material of electrical isolation 330 is joined to the material of heat spreader 130, e.g., with a direct compression bond or fusion bond.

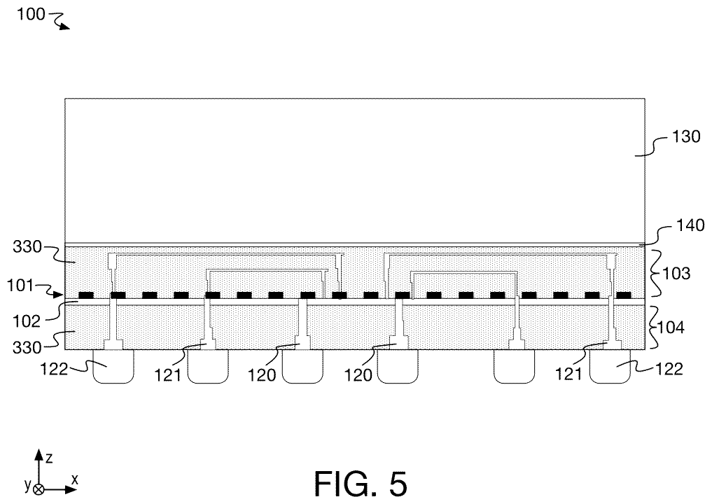

FIG. 5 illustrates a cross-sectional profile view of an example IC die 100, including transistors 101 and enhanced electrical isolations 330 for improved heat removal, in accordance with some embodiments. As shown in FIG. 5, transistors 101 are on substrate 102. One electrical isolation 330 is adjacent and above substrate 102 on front-side 103. Another electrical isolation 330 is adjacent and below substrate 102 on back-side 104. Electrical isolation 330 includes an insulating dielectric material, as well as a thermally conductive material that provides an enhanced, higher thermal conductance relative to the insulating dielectric material alone. Metallization structures 120, 121 connect transistors 101 to FLI interfaces 122. Heat spreader 130 is attached to upper electrical isolation 330 through bonding layer 140.

Both electrical isolations 330 include an insulating dielectric material and a second material with a higher relative permittivity and a higher thermal conductivity. The upper electrical isolation 330 provides improved heat removal (relative to an insulating dielectric material alone) upward through heat spreader 130. In some embodiments, heat is removed through heat spreader 130 to a heat sink above IC die 100 or to another IC die 100 in a stack of IC dies 100. The lower electrical isolation 330 provides improved heat removal downward. Heat can be dissipated to other structures below IC die 100. In some embodiments, heat is removed from transistors 101 through electrical isolation 330 to a package substrate below IC die 100 and a heat sink thermally coupled to the package substrate. In some embodiments, heat is removed downward to another IC die 100 in a stack of IC dies 100.

In some embodiments, upper electrical isolation 330 and lower electrical isolation 330 include the same materials using the same ratios of concentrations or layer thicknesses. In some embodiments, upper electrical isolation 330 and lower electrical isolation 330 include the same materials but have different ratios of concentrations or layer thicknesses. For example, in some embodiments, upper electrical isolation 330 includes the same insulating dielectric material as lower electrical isolation 330, but upper electrical isolation 330 has a lower concentration of the second material (with higher thermal conductivity and higher relative permittivity). The lower concentration could provide a lower relative permittivity (as may be required for signal metallization structures 121) while providing a satisfactory thermal conductivity. In another example, upper electrical isolation 330 includes the same insulating dielectric material as lower electrical isolation 330, but upper electrical isolation 330 has a higher concentration of the second material (with higher thermal conductivity and higher relative permittivity). The higher concentration provides improved thermal conductivity to prioritize heat removal upwards when, e.g., lower frequency signals through upper electrical isolation 330 allow for increased parasitic capacitances and resistance-capacitance (RC) delays. In some embodiments, upper electrical isolation 330 and lower electrical isolation 330 use different materials. In some embodiments, different layers within upper electrical isolation 330 and lower electrical isolation 330 use different structures, materials, chemical compositions, or concentrations than other layers. In some embodiments, some materials are only used in certain locations, e.g., on the frontside of substrate 102, in higher layers away from substrate 102, or in layers of metallization structures 120, 121 with wider line pitches.

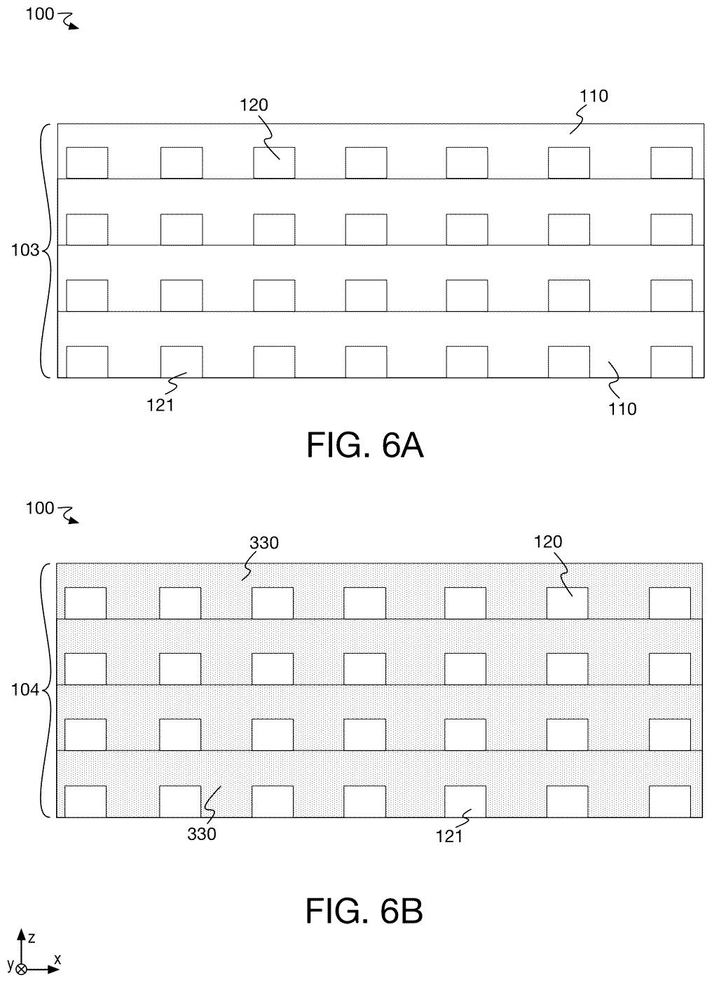

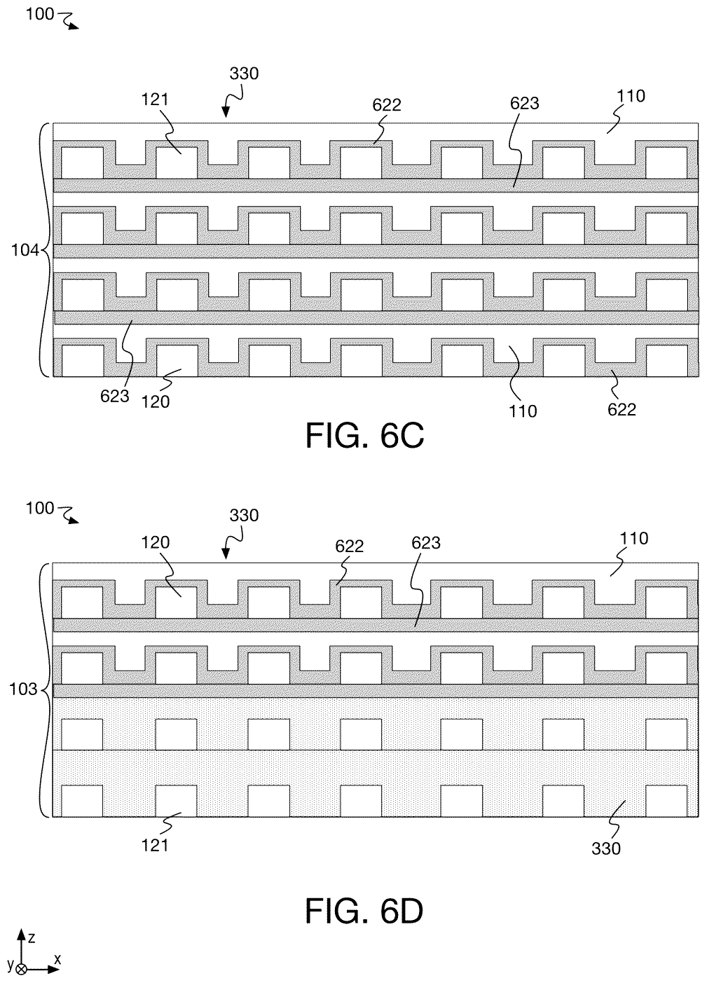

FIGS. 6A, 6B, 6C, and 6D illustrate cross-sectional profile views of some layers in portions of example IC dies 100, including enhanced electrical isolation 330 for improved heat removal, in accordance with some embodiments. FIGS. 6A-6D show metallization structures 120, 121 running through portions of multiple, adjacent layers of dielectric material 110 or electrical isolation 330. The figures show multiple layers, some with different materials or chemical composition or structure, including some embodiments with combinations of materials in layers. Some or all of the metal interconnects could be power metallization structures 120 and/or signal metallization structures 121. FIGS. 6B-6D show embodiments of electrical isolation 330 that can be used in any of the examples seen or discussed previously or subsequently. Multiple layers of electrical isolation 330 in FIGS. 6B-6D may be shown or discussed as a single or multiple layers of electrical isolation 330 in the figures.

FIG. 6A shows four layers of dielectric material 110 (or a single layer of dielectric material 110 with four layers of metallization structures 120, 121). The four layers of dielectric material 110 are on front-side 103 of an IC die 100, but they could instead or additionally be on a back-side. The four layers could be used as dielectric material 110 in any previous embodiments shown having dielectric material 110, including dielectric material 110 having power metallization structures 120 and/or signal metallization structures 121. As shown, different dielectric material 110 may correspond to different metallization layers.

FIG. 6B shows four layers of electrical isolation 330 with four layers of metallization structures 120, 121. The layers of electrical isolation 330 are on back-side 104 of IC die 100, but could instead or additionally be on a front-side. Electrical isolation 330 physically separates and electrically isolates metallization structures 120, 121. Electrical isolation 330 is formed from an enhanced homogenous dielectric material, an insulating dielectric material mixed with a second material having a higher relative permittivity and a higher thermal conductivity. In some embodiments, the insulating dielectric material is silicon dioxide. In some such embodiments, the silicon dioxide is mixed with boron arsenide. In some embodiments, the various material concentrations vary from layer to layer. In some embodiments, the second material concentration is higher in layers with higher current density to improve heat removal. In some embodiments, the second material concentration is lower in layers with tighter interconnect line pitches to minimize relative permittivity and associated RC delays due to parasitic capacitances.

As discussed previously, a homogenous dielectric material may be formed using CVD or other operations. In some embodiments, CVD operations are preferred for some locations or layer depths. As an example, CVD operations may be performed for layers on one side of the substrate, e.g., on a frontside of the substrate. In some embodiments, CVD operations are performed for layers near the substrate or with narrow metallization pitches.

FIG. 6C shows four layers of electrical isolation 330 and four layers of metallization structures 120, 121 on back-side 104 of IC die 100. A first material, insulating dielectric material 110, is interleaved with a second material, thermally conductive material 622, a material with a higher relative permittivity and a higher thermal conductivity. More layers of thermally conductive material 623 may also be interleaved with dielectric material 110 and thermally conductive material 622. Thermally conductive material 623 may be the same material as thermally conductive material 622 or another material with a higher relative permittivity and a higher thermal conductivity than dielectric material 110. As shown, thermally conductive materials 622, 623 may be over and under each metal line. In some embodiments, thermally conductive material 622 is over metallization structures 120, 121, which are on or in a layer or sublayer of dielectric material 110. In some embodiments, thermally conductive material 623 is under metallization structures 120, 121, which are in or below a layer of dielectric material 110. In some embodiments, thermally conductive material 622 is interleaved between layers of dielectric material 110 and metallization structures 120, 121. In some embodiments, one or more layering schemes are used for power metallization structures 120, and one or more other layering schemes are used for signal metallization structures 121. In some embodiments, the layering of thermally conductive materials 622, 623 and dielectric material 110 depends on the vertical spacing between metallization structures 120, 121. In some embodiments, the layering of thermally conductive materials 622, 623 and dielectric material 110 corresponds to factors other than metallization structures 120, 121, such as layer depth relative to a substrate.

Thermally conductive materials 622, 623 may be any suitable material. Well-suited materials have thermal conductivities higher than dielectric material 110 and low relative permittivities, advantageously as low as that of dielectric material 110. Higher electrical resistivities are beneficial so as avoid interfering with the operation of metallization structures 120, 121. In some embodiments, thermally conductive materials 622, 623 include particles of crystalline carbon, e.g., diamond. In some embodiments, crystalline carbon particles are deposited for some locations or depths and not for others. As an example, crystalline carbon may be deposited in upper layers, further from the substrate. In some embodiments, crystalline carbon is deposited only within layers with wide metallization pitches. In some embodiments, particles are deposited only within layers on one side of the substrate, e.g., on the backside.

In some embodiments, the same or a different insulating dielectric material 110 is mixed with a thermally conductive material to form an enhanced homogenous dielectric material, as in FIG. 6B, which is layered with thermally conductive material 622 instead of dielectric material 110.

FIG. 6D shows four layers of metallization structures 120, 121 in four layers of electrical isolation 330 on front-side 103 of IC die 100. Electrical isolation 330 incorporates at least one insulating dielectric material 110 and at least one thermally conductive material 622, 623. In the top two layers of electrical isolation 330, insulating dielectric material 110 is interleaved with thermally conductive materials 622, 623. In the bottom two layers of electrical isolation 330, an enhanced homogenous dielectric material is an insulating dielectric material mixed with a more thermally conductive material having a higher relative permittivity and a higher thermal conductivity. In some embodiments, the enhanced homogenous dielectric material is a mixture of dielectric material 110 and thermally conductive material 622. In other embodiments of the enhanced homogenous dielectric material, more or other chemical compositions or concentrations may be used. In some embodiments, an enhanced homogenous dielectric material is used instead of dielectric material 110 in the top two layers of electrical isolation 330.

In some embodiments, thermally conductive material 622 includes particles of crystalline carbon. In some embodiments, the enhanced homogenous dielectric material includes boron and arsenic in silicon and oxygen. In some embodiments, electrical isolation 330 having metallization structures 120, 121 with tighter dimensions (either laterally or vertically) includes the enhanced homogenous dielectric material, and electrical isolation 330 with larger dimensions include thermally conductive materials 622, 623 interleaved between dielectric material 110. In some embodiments, electrical isolation 330 with tighter dimensions include smaller particles of thermally conductive materials 622, 623 interleaved between dielectric material 110, and electrical isolation 330 with larger dimensions include larger particles of thermally conductive materials 622, 623. Different particle sizes can be used to vary characteristics of electrical isolation 330. In some embodiments, different electrical isolations 330 include smaller or larger particles of thermally conductive material, and different electrical isolations 330 have smaller or larger air gaps between particles. In some embodiments, smaller and larger thermally conductive particles are used together to control the size of air gaps between particles.

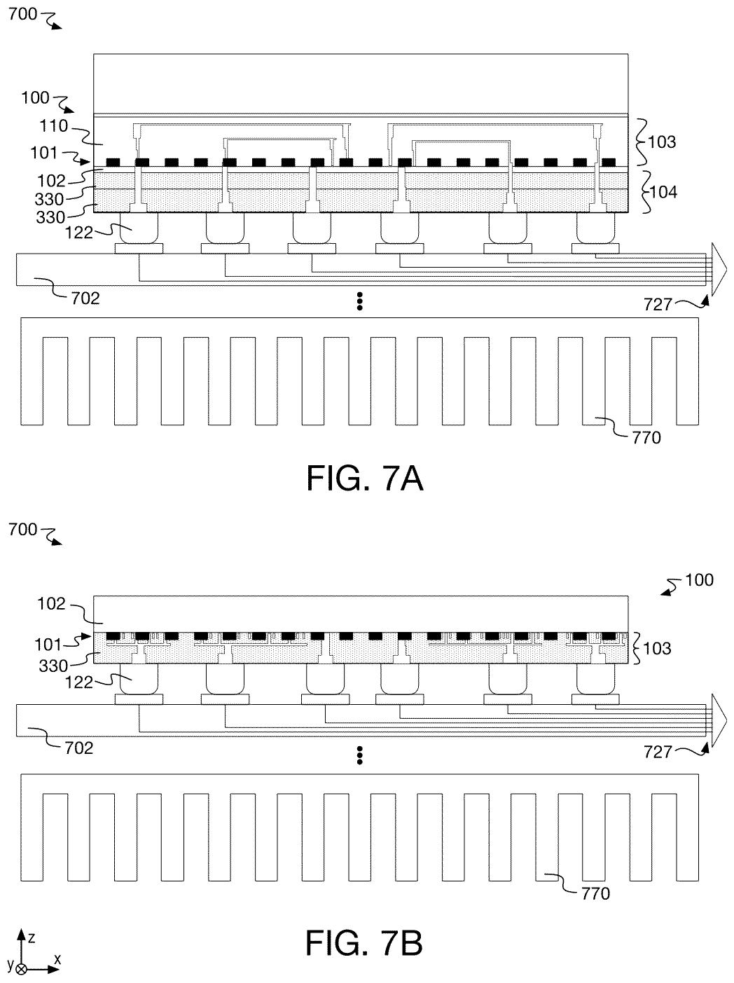

FIGS. 7A and 7B illustrate cross-sectional profile views of systems 700, including heat sinks 770 and IC dies 100 with enhanced electrical isolations 330 for improved heat removal, in accordance with some embodiments. FIG. 7A shows a system 700 with heat sink 770 thermally coupled to substrate 702, which is connected to a similar IC die 100 as that seen in FIG. 3. Multiple electrical isolations 330 on back-side 104 are shown in FIG. 7A, but the multiple electrical isolations 330 can be shown as a single electrical isolation 330 with multiple layers within it not separately shown, as in FIG. 3. IC die 100 has transistors 101 on front-side 103 of substrate 102 between dielectric material 110 and multiple electrical isolations 330. IC die 100 connects to substrate 702 at FLI interfaces 122. Heat sink 770 is thermally coupled to substrate 702 and IC die 100 opposite IC die 100. Conductive routes 727 electrically connect IC die 100 to substrate 702 via FLI interfaces 122. Conductive routes 727 also electrically connect IC die 100 to one or more power supplies, as well as other structures, devices, etc., connected to substrate 702.

Substrate 702 may be, e.g., a package substrate, such as an interposer. Substrate 702 has electrical connections to one or more power supplies and other electrical sources, e.g., control and I/O signals. Conductive routes 727 conduct power to or from IC die 100 and through substrate 702. In some embodiments, conductive routes 727 run vertically through substrate 702.

Heat sink 770 may be mounted directly to substrate 702. In some embodiments, heat sink 770 is vertically in line with IC die 100. In some embodiments, heat sink 770 is to one side or the other. In some embodiments, heat sink 770 is thermally coupled to substrate 702 and IC die 100 via one or more other structures, such as a heat spreader. In some embodiments, heat sink 770 dissipates thermal energy to air or another fluid. In some embodiments, heat sink 770 dissipates thermal energy to a coolant that flows over heat sink 770 by gravitational forces or other means, e.g., by a fan or pump. In some embodiments, heat sink 770 dissipates thermal energy to a liquid coolant with a low boiling point or a liquid coolant cooled below ambient temperature.

Electrical isolations 330 improve heat removal by enhancing heat dissipation from transistors 101 downward to substrate 702 and heat sink 770. Multiple electrical isolation 330 may include the same two materials, an insulating dielectric material and a more permittive and thermally conductive material. In some embodiments, different electrical isolations 330 include different combinations of materials.

FIG. 7B shows IC die 100 having transistors 101 on front-side 103 of substrate 102 adjacent electrical isolation 330. IC die 100 connects to substrate 702 at FLI interfaces 122. Heat sink 770 is thermally coupled to substrate 702 and IC die 100. Conductive routes 727 electrically connect IC die 100 to substrate 702 via FLI interfaces 122. Conductive routes 727 also electrically connect IC die 100 to one or more power supplies, as well as other structures, devices, etc., connected to substrate 702.

In some embodiments, substrate 102 is less thermally conductive, e.g., than silicon, and electrical isolation 330 improves heat dissipation downward to substrate 702 and heat sink 770. In some embodiments, for mechanical considerations, substrate 102 is not thinned, and electrical isolation 330 dissipates heat downward to substrate 702 and heat sink 770. In some embodiments, heat sink 770 is connected directly to substrate 702. In some embodiments, heat sink 770 is thermally coupled to substrate 702 and IC die 100 via one or more other structures. In some embodiments, heat sink 770 is mounted on another IC die 100, the die being on the lower surface of substrate 702.

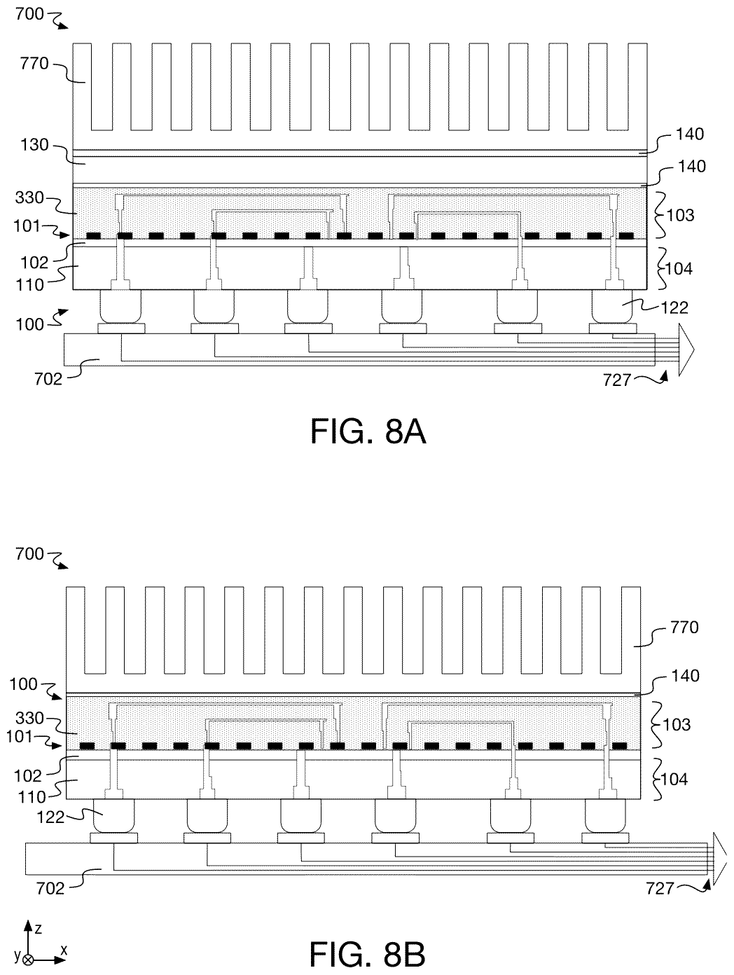

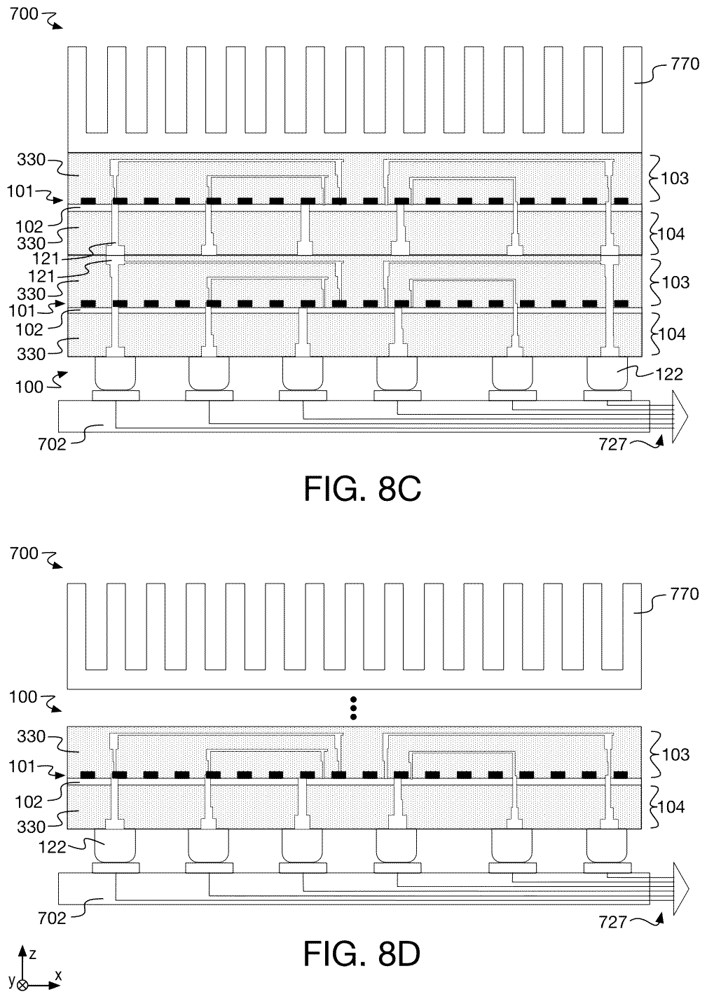

FIGS. 8A, 8B, 8C, and 8D illustrate cross-sectional profile views of systems 700, including heat sinks 770 and IC dies 100 with enhanced electrical isolation 330 for improved heat removal, in accordance with some embodiments. FIG. 8A shows a system 700 with heat sink 770 and substrate 702 connected to a similar IC die 100 as that seen in FIG. 4. IC die 100 has transistors 101 on front-side 103 of substrate 102 between electrical isolation 330 and dielectric material 110. Heat sink 770 is above and bonded to heat spreader 130 through upper bonding layer 140. Heat spreader 130 is bonded to electrical isolation 330 through lower bonding layer 140. FLI interfaces 122 electrically and mechanically connect IC die 100 to substrate 702. Conductive routes 727 electrically connect IC die 100 via FLI interfaces 122 to one or more power supplies, as well as other structures, devices, etc., connected to substrate 702. Heat dissipates upward through electrical isolation 330 to heat sink 770.

In some embodiments, heat spreader 130 is part of a larger structure, e.g., a carrier wafer used for other mechanical or handling purposes during earlier processing, before being diced out with IC die 100. In some embodiments, heat spreader 130 is not added to the structure of FIG. 8A. In some embodiments, heat spreader 130 is removed after fulfilling other uses, e.g., mechanical or handling purposes.

FIG. 8B shows a system 700 similar to that seen in FIG. 8A with heat sink 770 and substrate 702 connected to a similar IC die 100, but without heat spreader 130. IC die 100 has transistors 101 on substrate 102 between electrical isolation 330 and dielectric material 110. Heat sink 770 is above and bonded to electrical isolation 330 through bonding layer 140. FLI interfaces 122 electrically and mechanically connect IC die 100 to substrate 702. Conductive routes 727 electrically connect IC die 100 via FLI interfaces 122 to one or more power supplies, as well as other structures, devices, etc., connected to substrate 702. Heat dissipates upward through electrical isolation 330 to heat sink 770.

FIG. 8C shows a system 700 with heat sink 770 and substrate 702 connected to a stack of IC dies 100. IC dies 100 have transistors 101 on substrates 102 between electrical isolations 330. Heat sink 770 is above, and bonded through bonding layer 140, to an upper surface of the upper electrical isolation 330 of upper IC die 100. Upper and lower IC dies 100 are electrically connected by metallization structures 120, 121, e.g., by signal metallization structures 121, as shown, and by other connections (not shown). Lower IC die 100 connects to substrate 702 at FLI interfaces 122. FLI interfaces 122 electrically connect IC dies 100 to conductive routes 727 and substrate 702. Conductive routes 727 electrically connect IC dies 100 to one or more power supplies, as well as other structures, devices, etc., connected to substrate 702. Heat dissipates upward through electrical isolation 330 to heat sink 770 and downward through electrical isolation 330 to substrate 702.

FIG. 8D shows a system 700 with substrate 702 connected and heat sink 770 coupled to IC die 100. IC die 100 has transistors 101 on substrate 102 between multiple electrical isolations 330. FLI interfaces 122 electrically and mechanically connect IC die 100 to substrate 702. Conductive routes 727 electrically connect IC die 100 via FLI interfaces 122 to one or more power supplies, as well as other structures, devices, etc., connected to substrate 702. Heat sink 770 is above and thermally coupled to electrical isolation 330. Other structures potentially between electrical isolation 330 and heat sink 770 are not shown, but their potential presence is indicated by the ellipsis. Heat dissipates upward through electrical isolation 330 to heat sink 770 and downward through electrical isolation 330 to substrate 702.

Other structures may (or may not) be used above electrical isolation 330 to thermally couple electrical isolation 330 (and structures below, e.g., transistors 101) to heat sink 770. In some embodiments, one or more heat spreaders 130 are above electrical isolation 330 and below heat sink 770, as in FIG. 8A. In some embodiments, electrical isolation 330 is bonded to heat sink 770 directly or with, e.g., a thermally conductive adhesive, as in FIG. 8B. In some embodiments, another IC die 100 is above electrical isolation 330 and below heat sink 770, as in FIG. 8C. In some embodiments, multiple IC dies 100 are above electrical isolation 330 and below heat sink 770. Other suitable means are available for coupling electrical isolation 330 to heat sink 770 to remove heat from, e.g., transistors 101 and dissipate it upward.

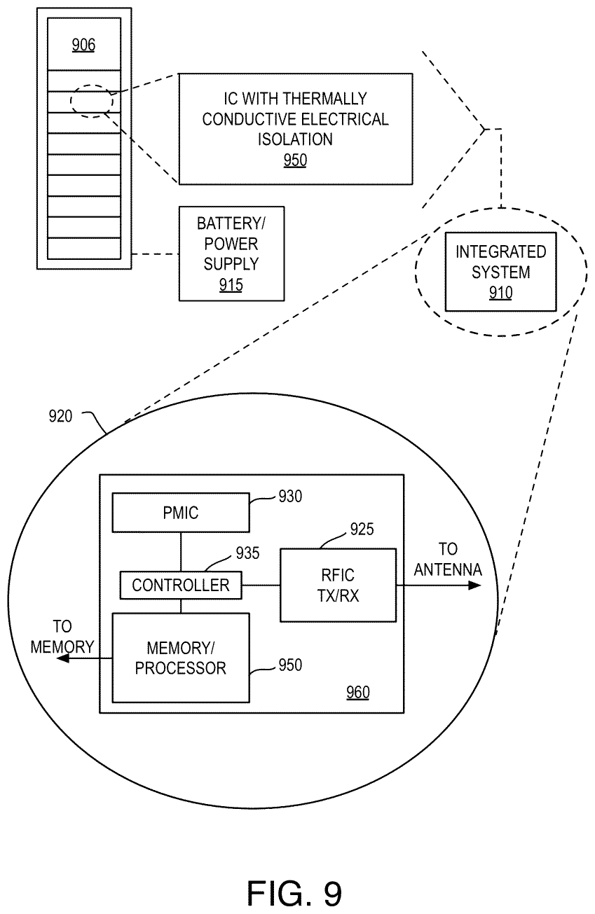

FIG. 9 illustrates a diagram of an example data server machine 906 employing IC dies with enhanced electrical isolation for improved heat removal, in accordance with some embodiments. Server machine 906 may be any commercial server, for example, including any number of high-performance computing platforms disposed within a rack and networked together for electronic data processing, which in the exemplary embodiment includes one or more devices 950 having an IC die with thermally conductive electrical isolation. In some embodiments, example data server machine 906 has low-temperature, active-cooling operable to remove heat from the IC to achieve any low operating temperature discussed herein.

Also as shown, server machine 906 includes a battery and/or power supply 915 to provide power to devices 950, and to provide, in some embodiments, power delivery functions such as power regulation. Devices 950 may be deployed as part of a package-level integrated system 910. Integrated system 910 is further illustrated in the expanded view 920. In the exemplary embodiment, devices 950 (labeled “Memory/Processor”) includes at least one memory chip (e.g., RAM), and/or at least one processor chip (e.g., a microprocessor, a multi-core microprocessor, or graphics processor, or the like) having the characteristics discussed herein. In an embodiment, device 950 is a microprocessor including an SRAM cache memory. As shown, device 950 may employ a die or device having any narrow-channel, non-planar transistors and/or related characteristics discussed herein. Device 950 may be further coupled to (e.g., communicatively coupled to) a board, a substrate, or an interposer 960 along with, one or more of a power management IC (PMIC) 930, RF (wireless) IC (RFIC) 925 including a wideband RF (wireless) transmitter and/or receiver (TX/RX) (e.g., including a digital baseband and an analog front end module further comprises a power amplifier on a transmit path and a low noise amplifier on a receive path), and a controller 935 thereof.

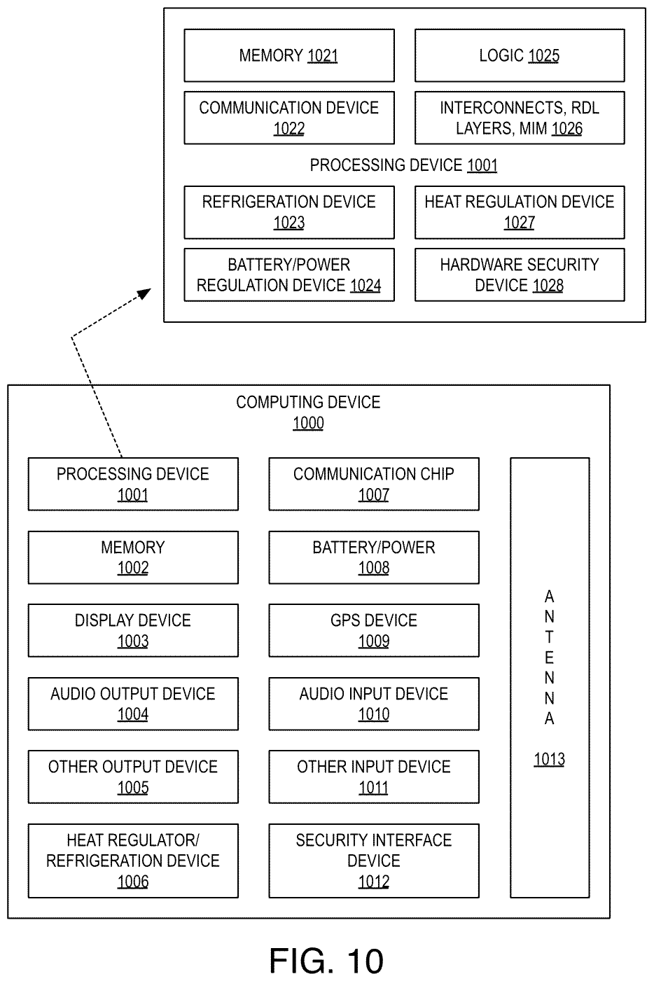

FIG. 10 is a block diagram of an example computing device 1000, in accordance with some embodiments. For example, one or more components of computing device 1000 may include any of the devices or structures discussed herein. A number of components are illustrated in FIG. 10 as being included in computing device 1000, but any one or more of these components may be omitted or duplicated, as suitable for the application. In some embodiments, some or all of the components included in computing device 1000 may be attached to one or more printed circuit boards (e.g., a motherboard). In some embodiments, various ones of these components may be fabricated onto a single system-on-a-chip (SoC) die. Additionally, in various embodiments, computing device 1000 may not include one or more of the components illustrated in FIG. 10, but computing device 1000 may include interface circuitry for coupling to the one or more components. For example, computing device 1000 may not include a display device 1003, but may include display device interface circuitry (e.g., a connector and driver circuitry) to which display device 1003 may be coupled. In another set of examples, computing device 1000 may not include an audio output device 1004, other output device 1005, global positioning system (GPS) device 1009, audio input device 1010, or other input device 1011, but may include audio output device interface circuitry, other output device interface circuitry, GPS device interface circuitry, audio input device interface circuitry, audio input device interface circuitry, to which audio output device 1004, other output device 1005, GPS device 1009, audio input device 1010, or other input device 1011 may be coupled.

Computing device 1000 may include a processing device 1001 (e.g., one or more processing devices). As used herein, the term “processing device” or “processor” indicates a device that processes electronic data from registers and/or memory to transform that electronic data into other electronic data that may be stored in registers and/or memory. Processing device 1001 may include a memory 1021, a communication device 1022, a refrigeration device 1023, a battery/power regulation device 1024, logic 1025, interconnects 1026 (i.e., optionally including redistribution layers (RDL) or metal-insulator-metal (MIM) devices), a heat regulation device 1027, and a hardware security device 1028.

Processing device 1001 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices.

Computing device 1000 may include a memory 1002, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 1002 includes memory that shares a die with processing device 1001. This memory may be used as cache memory and may include embedded dynamic random-access memory (eDRAM) or spin transfer torque magnetic random-access memory (STT-M RAM).

Computing device 1000 may include a heat regulation/refrigeration device 1006. Heat regulation/refrigeration device 1006 may maintain processing device 1001 (and/or other components of computing device 1000) at a predetermined low temperature during operation. This predetermined low temperature may be any temperature discussed herein.

In some embodiments, computing device 1000 may include a communication chip 1007 (e.g., one or more communication chips). For example, the communication chip 1007 may be configured for managing wireless communications for the transfer of data to and from computing device 1000. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 1007 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 1007 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 1007 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 1007 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 1007 may operate in accordance with other wireless protocols in other embodiments. Computing device 1000 may include an antenna 1013 to facilitate wireless communications and/or to receive other wireless communications (such as AM or FM radio transmissions).

In some embodiments, communication chip 1007 may manage wired communications, such as electrical, optical, or any other suitable communication protocols (e.g., the Ethernet). As noted above, communication chip 1007 may include multiple communication chips. For instance, a first communication chip 1007 may be dedicated to shorter-range wireless communications such as Wi-Fi or Bluetooth, and a second communication chip 1007 may be dedicated to longer-range wireless communications such as GPS, EDGE, GPRS, CDMA, WiMAX, LTE, EV-DO, or others. In some embodiments, a first communication chip 1007 may be dedicated to wireless communications, and a second communication chip 1007 may be dedicated to wired communications.

Computing device 1000 may include battery/power circuitry 1008. Battery/power circuitry 1008 may include one or more energy storage devices (e.g., batteries or capacitors) and/or circuitry for coupling components of computing device 1000 to an energy source separate from computing device 1000 (e.g., AC line power).

Computing device 1000 may include a display device 1003 (or corresponding interface circuitry, as discussed above). Display device 1003 may include any visual indicators, such as a heads-up display, a computer monitor, a projector, a touchscreen display, a liquid crystal display (LCD), a light-emitting diode display, or a flat panel display, for example.

Computing device 1000 may include an audio output device 1004 (or corresponding interface circuitry, as discussed above). Audio output device 1004 may include any device that generates an audible indicator, such as speakers, headsets, or earbuds, for example.

Computing device 1000 may include an audio input device 1010 (or corresponding interface circuitry, as discussed above). Audio input device 1010 may include any device that generates a signal representative of a sound, such as microphones, microphone arrays, or digital instruments (e.g., instruments having a musical instrument digital interface (MIDI) output).

Computing device 1000 may include a GPS device 1009 (or corresponding interface circuitry, as discussed above). GPS device 1009 may be in communication with a satellite-based system and may receive a location of computing device 1000, as known in the art.

Computing device 1000 may include other output device 1005 (or corresponding interface circuitry, as discussed above). Examples of the other output device 1005 may include an audio codec, a video codec, a printer, a wired or wireless transmitter for providing information to other devices, or an additional storage device.

Computing device 1000 may include other input device 1011 (or corresponding interface circuitry, as discussed above). Examples of the other input device 1011 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 1000 may include a security interface device 1012. Security interface device 1012 may include any device that provides security measures for computing device 1000 such as intrusion detection, biometric validation, security encode or decode, access list management, malware detection, or spyware detection.

Computing device 1000, or a subset of its components, may have any appropriate form factor, such as a hand-held or mobile computing device (e.g., a cell phone, a smart phone, a mobile internet device, a music player, a tablet computer, a laptop computer, a netbook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

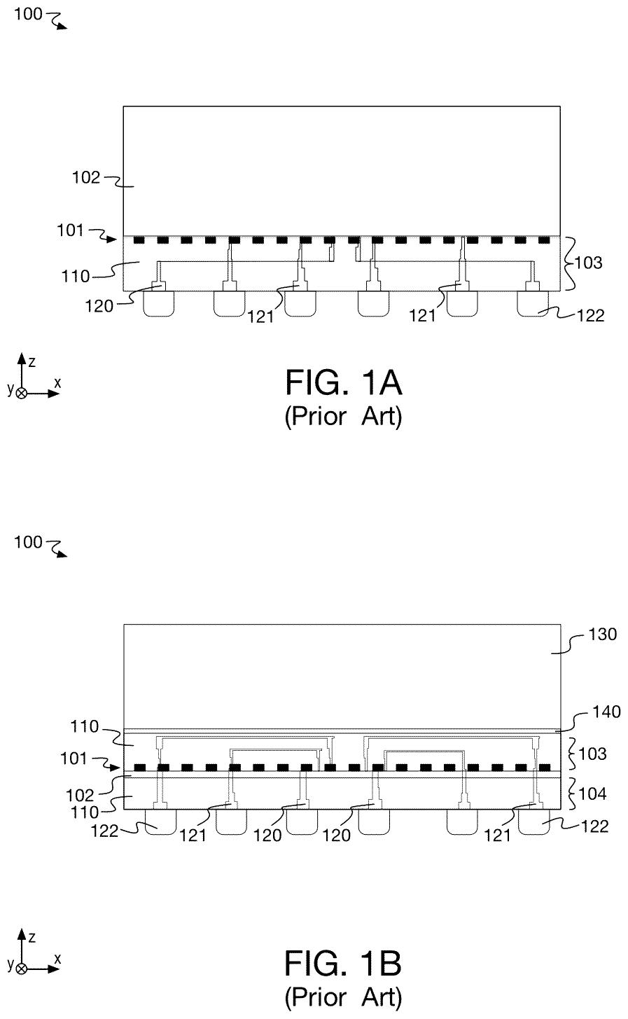

The subject matter of the present description is not necessarily limited to specific applications illustrated in FIGS. 1-10. The subject matter may be applied to other deposition applications, as well as any appropriate manufacturing application, as will be understood to those skilled in the art.

The following examples pertain to further embodiments, and specifics in the examples may be used anywhere in one or more embodiments.

In one or more first embodiments, an IC die comprises a substrate comprising a crystalline material, a plurality of transistors on a first side of the substrate, a first metallization structure on the first side of the substrate and coupled to one or more of the transistors, a second metallization structure on a second side of the substrate, opposite the first side, and coupled to one or more of the transistors, and electrical isolation on the first side or the second side of the substrate, the electrical isolation comprising silicon and oxygen, and either crystalline carbon or both of boron and arsenic.

In one or more second embodiments, further to the first embodiments, the first metallization structure comprises a plurality of signal lines having a first minimum pitch, the second metallization structure comprises a plurality of power rail lines having a second minimum pitch, larger than the first minimum pitch, the electrical isolation is between the substrate and a plurality of FLI interfaces, and the second metallization structure is embedded within the electrical isolation.

In one or more third embodiments, further to the first or second embodiments, the electrical isolation is on the first side of the substrate, and the first metallization structure is embedded within the electrical isolation.

In one or more fourth embodiments, further to the first through third embodiments, the electrical isolation is between the transistors and a heat spreader.

In one or more fifth embodiments, further to the first through fourth embodiments, the heat spreader comprises predominantly silicon.

In one or more sixth embodiments, further to the first through fifth embodiments, the electrical isolation comprises predominantly silicon, oxygen, boron, and arsenic.

In one or more seventh embodiments, further to the first through sixth embodiments, the electrical isolation is a composite comprising a first material and a second material, the first material comprises silicon and oxygen, and the second material is crystalline carbon.

In one or more eighth embodiments, further to the first through seventh embodiments, particles of the second material are embedded in the first material.

In one or more ninth embodiments, further to the first through eighth embodiments, the electrical isolation comprises a first layer comprising the first material and a second layer comprising the second material.

In one or more tenth embodiments, further to the first through ninth embodiments, the electrical isolation comprises predominantly silicon, oxygen, boron, arsenic, and crystalline carbon.

In one or more eleventh embodiments, further to the first through tenth embodiments, the crystalline material is predominantly silicon.

In one or more twelfth embodiments, a system comprises a substrate, a power supply, and an IC die attached to the substrate and coupled to the power supply, the IC die comprising a plurality of transistors, and electrical isolation between the substrate and the transistors, the electrical isolation comprising silicon and oxygen, and either crystalline carbon or both of boron and arsenic.

In one or more thirteenth embodiments, further to the twelfth embodiments, the electrical isolation comprises boron and arsenic.

In one or more fourteenth embodiments, further to the twelfth or thirteenth embodiments, the electrical isolation comprises a layer of a first material and a layer of a second material, the first material comprises silicon and oxygen, and the second material is crystalline carbon.

In one or more fifteenth embodiments, further to the twelfth through fourteenth embodiments, a heat sink is thermally coupled to the substrate on a side of the substrate distal from the IC die.

In one or more sixteenth embodiments, further to the twelfth through fifteenth embodiments, a heat sink is thermally coupled to the IC die between the heat sink and the substrate, the IC die further comprising the electrical isolation between the transistors and the heat sink.

In one or more seventeenth embodiments, a method comprises receiving a substrate with transistors on a frontside of the substrate, depositing, on a backside of the substrate, an electrically insulating material comprising silicon and oxygen, and either crystalline carbon or both of boron and arsenic, and forming metallization structures through the electrically insulating material.

In one or more eighteenth embodiments, further to the seventeenth embodiments, depositing the electrically insulating material comprises a chemical vapor deposition with precursor gases comprising the silicon, oxygen, boron and arsenic.

In one or more nineteenth embodiments, further to the seventeenth or eighteenth embodiments, depositing the electrically insulating material comprises depositing particles comprising at least the crystalline carbon.

In one or more twentieth embodiments, further to the seventeenth through nineteenth embodiments, the depositing comprises depositing layers of different composition, and a first of the layers comprises the particles.

In one or more twenty-first embodiments, further to the seventeenth through twentieth embodiments, depositing particles comprises cold spraying the particles.

The disclosure can be practiced with modification and alteration, and the scope of the appended claims is not limited to the embodiments so described. For example, the above embodiments may include specific combinations of features. However, the above embodiments are not limiting in this regard and, in various implementations, the above embodiments may include the undertaking only a subset of such features, undertaking a different order of such features, undertaking a different combination of such features, and/or undertaking additional features than those features explicitly listed. The scope of the patent rights should, therefore, be determined with reference to the appended claims, along with the full scope of equivalents to which such claims are entitled.

We claim:

1. An integrated circuit (IC) die, comprising:
a substrate comprising a crystalline material;
a plurality of transistors on a first side of the substrate;
a first metallization structure on the first side of the substrate and coupled to one or more of the transistors;
a second metallization structure on a second side of the substrate, opposite the first side, and coupled to one or more of the transistors; and
electrical isolation on the first side or the second side of the substrate, the electrical isolation comprising silicon and oxygen, and either crystalline carbon or both of boron and arsenic.

2. The IC die of claim 1, wherein:
the first metallization structure comprises a plurality of signal lines having a first minimum pitch;
the second metallization structure comprises a plurality of power rail lines having a second minimum pitch, larger than the first minimum pitch;
the electrical isolation is between the substrate and a plurality of first-level interconnect (FLI) interfaces; and
the second metallization structure is embedded within the electrical isolation.

3. The IC die of claim 2, further comprising the electrical isolation on the first side of the substrate, wherein the first metallization structure is embedded within the electrical isolation.

4. The IC die of claim 1, wherein the electrical isolation is between the transistors and a heat spreader.

5. The IC die of claim 4, wherein the heat spreader comprises predominantly silicon.

6. The IC die of claim 1, wherein the electrical isolation comprises predominantly silicon, oxygen, boron, and arsenic.

7. The IC die of claim 1, wherein:
the electrical isolation is a composite comprising a first material and a second material;
the first material comprises silicon and oxygen; and
the second material is crystalline carbon.

8. The IC die of claim 7, wherein particles of the second material are embedded in the first material.

9. The IC die of claim 7, wherein the electrical isolation comprises a first layer comprising the first material and a second layer comprising the second material.

10. The IC die of claim 1, wherein the electrical isolation comprises predominantly silicon, oxygen, boron, arsenic, and crystalline carbon.

11. The IC die of claim 1, wherein the crystalline material is predominantly silicon.

12. A system, comprising:
a substrate;
a power supply; and
an integrated circuit (IC) die attached to the substrate and coupled to the power supply, the IC die comprising:
a plurality of transistors; and
electrical isolation between the substrate and the transistors, the electrical isolation comprising silicon and oxygen, and either crystalline carbon or both of boron and arsenic.

13. The system of claim 12, wherein the electrical isolation comprises boron and arsenic.

14. The system of claim 12, wherein:
the electrical isolation comprises a layer of a first material and a layer of a second material;
the first material comprises silicon and oxygen; and
the second material is crystalline carbon.

15. The system of claim 12, further comprising a heat sink thermally coupled to the substrate, the heat sink coupled to the substrate on a side of the substrate distal from the IC die.

16. The system of claim 12, further comprising a heat sink thermally coupled to the IC die, the IC die between the heat sink and the substrate, the IC die further comprising the electrical isolation between the transistors and the heat sink.

17. A method, comprising:
receiving a substrate with transistors on a frontside of the substrate;
depositing, on a backside of the substrate, an electrically insulating material comprising silicon and oxygen, and either crystalline carbon or both of boron and arsenic; and
forming metallization structures through the electrically insulating material.

18. The method of claim 17, wherein depositing the electrically insulating material comprises a chemical vapor deposition with precursor gases comprising the silicon, oxygen, boron and arsenic.

19. The method of claim 17, wherein depositing the electrically insulating material comprises depositing particles comprising at least the crystalline carbon.

20. The method of claim 19, wherein the depositing comprises depositing layers of different composition, and a first of the layers comprises the particles.

21. The method of claim 19, wherein depositing particles comprises cold spraying the particles.
